(19) United States
(12) Patent Application Publication
(10) Pub. No.: US 2020/0260609 A1
(43) Pub. Date: Aug. 13, 2020

(54) THERMAL MANAGEMENT SOLUTIONS FOR INTEGRATED CIRCUIT PACKAGES

(71) Applicant: Intel Corporation, Santa Clara, CA (US)

(72) Inventors: Amitesh Saha, Phoenix, AZ (US); Je-Young Chang, Phoenix, AZ (US); Betsegaw K. Gebrehiwot, Chandler, AZ (US)

(73) Assignee: Intel Corporation, Santa Clara, CA (US)

(21) Appl. No.: 16/273,633

(22) Filed: Feb. 12, 2019

(51) Int. Cl. H05K 7/20; H01L 23/373; H05K 1/02

(52) U.S. Cl. CPC H05K 7/205; H05K 1/0206; H05K 7/20436; H01L 23/373

(57) ABSTRACT

A heat dissipation device may be formed having a planar structure with a first surface and a surface area enhancement structure projecting from or extending into the first surface of the planar structure. In one embodiment, an integrated circuit package may be formed with the heat dissipation device, wherein the heat dissipation device and at least one integrated circuit device are brought into thermal contact with a thermal interface material between the at least one integrated circuit device and the heat dissipation device and wherein the surface area enhancement structure of the heat dissipation device directly contacts the thermal interface material.

### TECHNICAL FIELD

Embodiments of the present description generally relate to the removal of heat from integrated circuit devices, and, more particularly, to thermal management solutions which utilize structures for preventing thermal interface materials from flowing from between integrated circuit devices and a heat dissipation device.

### BACKGROUND

Higher performance, lower cost, increased miniaturization, and greater packaging density of integrated circuits within integrated circuit devices are ongoing goals of the electronics industry. As these goals are achieved, the density of power consumption of components within the integrated circuit devices has increased, which, in turn, increases the average junction temperature of the integrated circuit device. If the temperature of the integrated circuit device becomes too high, circuits within the integrated circuit device may be damaged or destroyed. Thus, heat dissipation devices are used to remove heat from the integrated circuit devices in an integrated circuit package. In one example, at least one integrated circuit device may be mounted to a substrate and the heat dissipation device may be attached to the substrate and extend over the integrated circuit device(s) to form the integrated circuit package. The distance between the integrated circuit device(s) and the heat dissipation device is known as the bondline thickness.

A thermal interface material is disposed between the integrated circuit device(s) and the heat dissipation device to form thermal contact therebetween. The thermal efficiency of the thermal interface material is critical to effectively remove heat from the integrated circuit device(s). Thus, high thermal efficiency materials, such as two-phase metallic alloys, may be used as thermal interface materials. As will be understood to those skilled in the art, two-phase metallic alloys are composed of aggregates of two different phases, wherein the individual phases making up the two-phase alloy are different from one another in their composition or structure. The two-phase metallic alloys may provide excellent thermal performance due to their high thermal conductivities, e.g. about 20 W/mK, and due to excellent surface wetting, e.g. low contact resistance. The two-phase metallic alloys may also provide assembly benefits as no backside metallization wafer is required, no flux process is required, pick and place assembly can be used, and there is superior re-workability, as will be understood to those skilled in the art. The two-phase metallic alloys may further provide condition benefits as they are highly conformable, which may result in self-adjusting bondline thicknesses, and have substantially no shear stress implications, and thus substantially no delamination issues.

Although two-phase metallic alloys have advantages, they also have a tendency to flow out (i.e. pump-out/bleed-out) when subjected to temperature cycles during the operation of the integrated circuit package, especially when it is in a two-phase state. The temperature cycles cause warpage in integrated circuit device(s) within the integrated circuit package when it heats and cools during operation. For example, in a standard integrated circuit package with one integrated circuit, the heat dissipation device bottoms out at approximately the center of the integrated circuit device, due to the integrated circuit device's natural convex shape at room temperature. When the integrated circuit package is exposed to temperature gradients, the shape of the integrated circuit device changes from convex to flat or concave, which causes compression on the thermal interface material at edges or sidewalls of the integrated circuit device. When the integrated circuit package returns to room temperature, the integrated circuit device returns to a convex shape creating an elongation of the thermal interface material at the edge or sidewalls of the integrated circuit device. The mechanisms of compression and elongation may cause pump-out, which may result in the formation of an air-gap, also known as an air insulation layer, between the integrated circuit device and the heat dissipation device, which increases thermal resistance therebetween.

Attempts have been made to prevent the flow out the thermal interface materials, such as the use of sealant barriers. However, these attempts have not been entirely successful.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 is a side cross-sectional view of an integrated circuit assembly having a heat dissipation structure in thermal contact with an integrated circuit device, according to an embodiment of the present description.

FIGS. 2-4 are close-up side cross-sectional views of the integrated circuit assembly of FIG. 1 illustrating surface area enhancement structures formed in the heat dissipation structure, according to an embodiment of the present description.

FIGS. 5-7 are plan views along view A-A of any of FIGS. 2-4 illustrating surface area enhancement structures formed in the heat dissipation structure, according to various embodiments of the present description.

FIGS. 8-10 is a close-up side cross-sectional view of the integrated circuit assembly of FIG. 1 illustrating surface area enhancement structures formed in the integrated circuit device, according to an embodiment of the present description.

FIG. 11 is a plan views along views B-B of any of FIGS. 8-10 illustrating surface area enhancement structures formed in the integrated circuit device, according to an embodiment of the present description.

FIG. 12 is a side cross-sectional view of an integrated circuit assembly having a heat dissipation structure in thermal contact with an integrated circuit device with a sealant barrier between the heat dissipation structure and the integrated circuit device, according to an embodiment of the present description.

FIG. 13 is a flow diagram of a method for fabricating an integrated circuit assembly, according to various embodiments of the present description.

FIG. 14 is an electronic device/system, according to an embodiment of the present description.

### DESCRIPTION OF EMBODIMENTS

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present invention. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “cored” generally refers to a substrate of an integrated circuit package built upon a board, card or wafer comprising a non-flexible stiff material. Typically, a small printed circuit board is used as a core, upon which integrated circuit device and discrete passive components may be soldered. Typically, the core has vias extending from one side to the other, allowing circuitry on one side of the core to be coupled directly to circuitry on the opposite side of the core. The core may also serve as a platform for building up layers of conductors and dielectric materials.

Here, the term “coreless” generally refers to a substrate of an integrated circuit package having no core. The lack of a core allows for higher-density package architectures. as the through-vias have relatively large dimensions and pitch compared to high-density interconnects.

Here, the term “land side”, if used herein, generally refers to the side of the substrate of the integrated circuit package closest to the plane of attachment to a printed circuit board, motherboard, or other package. This is in contrast to the term “die side”, which is the side of the substrate of the integrated circuit package to which the die or dice are attached.

Here, the term “dielectric” generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate.

Here, the term “metallization” generally refers to metal layers formed over and through the dielectric material of the package substrate. The metal layers are generally patterned to form metal structures such as traces and bond pads. The metallization of a package substrate may be confined to a single layer or in multiple layers separated by layers of dielectric.

Here, the term “bond pad” generally refers to metallization structures that terminate integrated traces and vias in integrated circuit packages and dies. The term “solder pad” may be occasionally substituted for “bond pad” and carries the same meaning.

Here, the term “solder bump” generally refers to a solder layer formed on a bond pad. The solder layer typically has a round shape, hence the term “solder bump”.

Here, the term “substrate” generally refers to a planar platform comprising dielectric and metallization structures. The substrate mechanically supports and electrically couples one or more IC dies on a single platform, with encapsulation of the one or more IC dies by a moldable dielectric material. The substrate generally comprises solder bumps as bonding interconnects on both sides. One side of the substrate, generally referred to as the “die side”, comprises solder bumps for chip or die bonding. The opposite side of the substrate, generally referred to as the “land side”, comprises solder bumps for bonding the package to a printed circuit board.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

Embodiments of the present description include a heat dissipation device formed having a planar structure with a first surface and a surface area enhancement structure projecting from or extending into the first surface of the planar structure. In one embodiment, an integrated circuit package may be formed with the heat dissipation device, wherein the heat dissipation device and at least one integrated circuit device are brought into thermal contact with a thermal interface material between the at least one integrated circuit device and the heat dissipation device and wherein the surface area enhancement structure of the heat dissipation device directly contacts the thermal interface material.

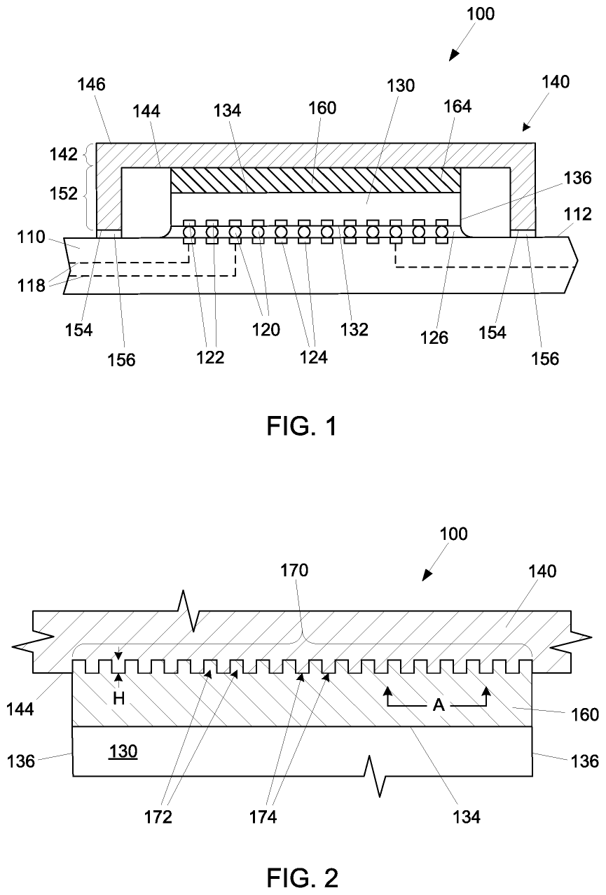

As shown in FIG. 1, an integrated circuit package 100 may be formed by first providing or forming an electronic substrate 110, such as an interposer, a printed circuit board, a motherboard, or the like. At least one integrated circuit device 130 may be attached to a first surface 112 of the electronic substrate 110 with a plurality of interconnects 120. The plurality of interconnects 120 may extend between bond pads 122 formed in or on a first surface 132 (also known as the “active surface”) of the integrated circuit device 130, and substantially mirror-image bond pads 124 in or on the first surface 112 of the electronic substrate 110. The at least one integrated circuit device 130 may further include a second surface 134 (also known as the “back surface”) opposing the first surface 132 and at least one side 136 extending between the first surface 132 and the second surface 134 of the at least one integrated circuit device 130. The least one integrated circuit device 130 may be any appropriate device, including, but not limited to, a microprocessor, a multichip package, a chipset, a graphics device, a wireless device, a memory device, an application specific integrated circuit device, combinations thereof, stacks thereof, or the like. The interconnects 120 may be any appropriate electrically conductive material, including, but not limited to, metal filled epoxies and solders, such as tin, lead/tin alloys (for example, 63% tin/37% lead solder), and high tin content alloys (e.g. 90% or more tin—such as tin/bismuth, eutectic tin/silver, ternary tin/silver/copper, eutectic tin/copper, and similar alloys).

An underfill material 126, such as an epoxy material, may be disposed between the first surface 132 of the integrated circuit device 130 and the first surface 112 of the electronic substrate 110, and surrounding the plurality of interconnects 120. As will be understood to those skilled in the art, the underfill material 126 may be dispensed between the first surface 132 of the integrated circuit device 130 and the first surface 112 of the electronic substrate 110 as a viscous liquid and then hardened with a curing process. The underfill material 126 may also be a molded underfill material. The underfill material 126 may provide structural integrity and may prevent contamination, as will be understood to those skilled in the art.

As further shown in FIG. 1, the electronic substrate 110 may provide electrical communication routes (illustrated as dashed lines 118) between the integrated circuit device 130 and external components (not shown). As will be understood to those skilled in the art, the bond pads 122 of the integrated circuit device 130 may be in electrical communication with integrated circuitry (not shown) within the integrated circuit device 130.

The electronic substrate 110 may comprise a plurality of dielectric material layers (not shown), which may include build-up films and/or solder resist layers, and may be composed of an appropriate dielectric material, including, but not limited to, bismaleimide triazine resin, fire retardant grade 4 material, polyimide material, silica filled epoxy material, glass reinforced epoxy material, and the like, as well as low-k and ultra low-k dielectrics (dielectric constants less than about 3.6), including, but not limited to, carbon doped dielectrics, fluorine doped dielectrics, porous dielectrics, organic polymeric dielectrics, and the like. The conductive routes 118 may be a combination of conductive traces (not shown) and conductive vias (not shown) extending through the plurality of dielectric material layers (not shown). These conductive traces and conductive vias are well known in the art and are not shown in FIG. 1 for purposes of clarity. The conductive traces and the conductive vias may be made of any appropriate conductive material, including but not limited to, metals, such as copper, silver, nickel, gold, and aluminum, alloys thereof, and the like. As will be understood to those skilled in the art, the electronic substrate 110 may be a cored substrate or a coreless substrate.

As further shown in FIG. 1, a heat dissipation device 140 may be attached to the electronic substrate 110. The heat dissipation device 140 may include a planar structure 142 having a first surface 144 and an opposing second surface 146, and may have at least one extension 152 projecting from the first surface 144 of the planar structure 142 of the heat dissipation device 140. The heat dissipation device extension(s) 152 may be attached to the first surface 112 of the electronic substrate 110 such that the first surface 144 of the planar structure 142 spans, but does not necessarily directly contact a second surface 134 (e.g. opposing the first surface 132) of the integrated circuit device 130, and a thermal interface material 160 may be disposed between the first surface 144 of the planar structure 142 of the heat dissipation device 140 and the second surface 134 of the integrated circuit device 130. The heat dissipation device extension(s) 152 may be attached to the electronic substrate 110 by any appropriate means, including but not limited to a sealant material 156, such as an epoxy, disposed between an attachment surface 154 of the heat dissipation device extension(s) 152 and the first surface 112 of the electronic substrate 110. In one embodiment, the heat dissipation device extension(s) 152 extend substantially perpendicular to the first surface 144 of the planar structure 142 of the heat dissipation device 140. It is understood that the term substantially perpendicular includes the heat dissipation device extension(s) 152 being plus or minus 5 degrees from 90 degrees.

The heat dissipation device 140 may be formed from any appropriate thermally conductive material, including, but not limited to copper, aluminum, and the like. In one embodiment, the heat dissipation device 140 may be formed from a molding or a stamping process, such that the heat dissipation device 140 is a single continuous material. In another embodiment, the planar structure 142 of the heat dissipation device 140 may be formed separately from the extension(s) 152 of heat dissipation device 140 and attached together.

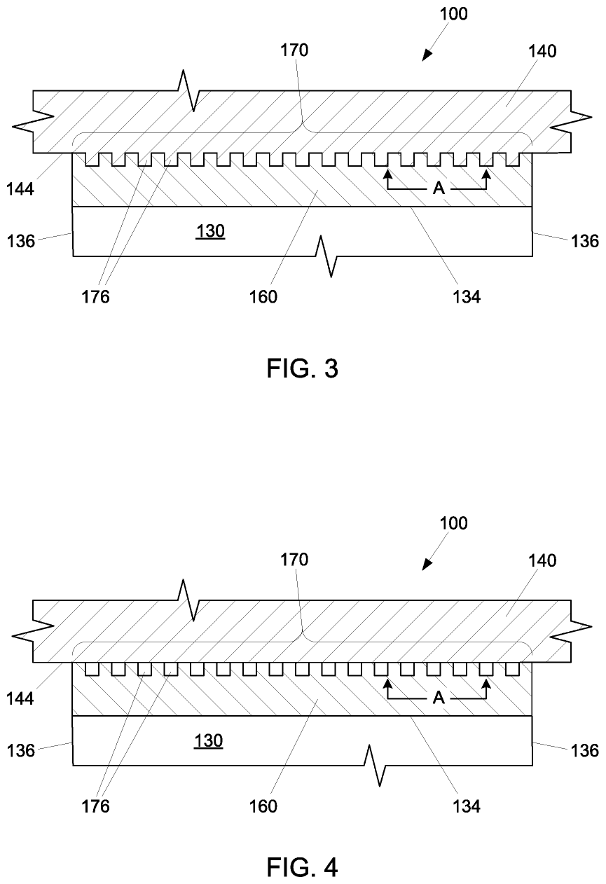

As shown in FIG. 2, a surface area enhancement structure 170 may be formed in or on the first surface 144 of the planar structure 142 of the heat dissipation device 140. FIG. 2 illustrates at least one recess 172 extending into the heat dissipation device 140 from the first surface 144 of the planar structure 142 of the heat dissipation device 140. It will be understood to those skilled in the art, the at least one recess 172 may form a plurality of individual recesses, which may be formed by processes including but not limited to etching, laser ablating, ion bombardment, stamping, and the like. As will be further understood to those skilled in the art, the at least one recess 172 may be a single recess such that portions 174 of the heat dissipation device 140 within the surface area enhancement structure 170 are projection or pillar-like structures, which may be formed after the formation of the heat dissipation device 140 by processes, including but not limited to etching, laser ablating, ion bombardment, skiving, milling, and the like, after the formation of the planar structure 142, or which may be formed by the process used to form the heat dissipation device 140 during the formation thereof, including but not limited to stamping, molding, or the like. As shown in the FIGS. 3 and 4, the surface area enhancement structure 170 may be plurality of projections 176 extending from the first surface 144 of the planar structure 142 of the heat dissipation device 140. In the embodiment shown in FIG. 3, the projections 176 may be formed after the formation of the heat dissipation device 140 by processes, including but not limited to etching, laser ablating, ion bombardment, skiving, milling, and the like, or which may be formed by the process used to form the heat dissipation device 140 during the formation thereof, including but not limited to stamping, molding, or the like. In the embodiment shown in FIG. 4, the projection 176 may be formed after the formation of the heat dissipation device 140 by plating, build-up, lamination, and the like.

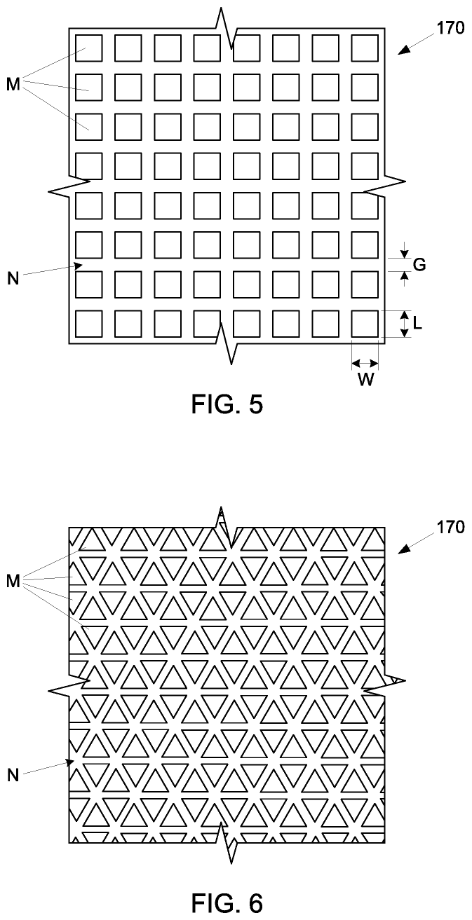

The recesses and projections, as shown in FIGS. 2-4, may have any appropriate shape. For example, elements M may have a substantially square cross-section in FIG. 5, a substantially triangular cross-section in FIG. 6, and a substantially circular cross-section in FIG. 7. It is noted that FIGS. 5-7 are plan views along line A-A of any of FIGS. 2-4 without the thermal interface material 160 for clarity. Elements M may represent the plurality of individual recesses 172 with regard to the first embodiment discussed with regard to FIG. 2, as discussed above, (with element N representing the first surface 144 of the planar structure 142 of the heat dissipation device 140) or element N may represent a single recess 172 with regard to the second embodiment discussed with regard to FIG. 2, as discussed above, (with element M representing pillar or projection structures). Elements M may represent the plurality of projections 176 with regard to the embodiments of FIGS. 3 and 4, as discussed above, (with element N representing the first surface 144 of the planar structure 142 of the heat dissipation device 140).

The surface area enhancement structure 170 can induce better adhesion by introducing more surface area for better wetting that would arrest movement of thermal interface material 160 and prevent it from flowing and/or being pumped out from between the heat dissipation device 140 and the at least one integrated circuit device 130. Thus, thermal interface materials 160 that are highly susceptible to movement, such as two-phase metallic alloys, may be used with the embodiment of the present description. In one embodiment, the thermal interface material 160 may be a two-phase metallic alloy, which have a liquidus temperature value and a solidus temperature value determined in part by the ratio of quantities of the metallic constitutes. The metallic constitutes may include, but not limited to, Bismuth (Bi), Lead (Pb), Tin (Sn), Cadmium (Cd), Antimony (Sb), Indium (In), Thallium (Tl), Tellurium (Te), Selenium (Se), Gallium (Ga), and Mercury (Hg).

Furthermore, the relative dimensions and positions of the recesses/projections of the surface area enhancement structure 170 may dictate the pinning and entrapping efficiency of the thermal interface material 160. These relative dimensions may include the average width W/length L (see FIG. 5) or average diameter D (see FIG. 7) of the recesses/projections M and the height H (see FIG. 2) thereof, as well as the distance or gap G (see FIGS. 5 and 7) between the recesses/projections M. It has been found that smaller relative dimensions arrest pump-out/bleed-out, increase adhesion at the interfaces, and reduce delamination. In one embodiment, the average width W (see FIG. 5), the average length L (see FIG. 5), or average diameter D (see FIG. 7) may be between about 1 micron and 400 microns, and, in a more specific embodiment, may be between about 25 microns and 200 microns. In a further embodiment, the distance or gap G (see FIGs, 5 and 7) may be between about 1 micron and 400 microns, and, in a more specific embodiment, may be between about 25 microns and 200 microns. In still a further embodiment, the height H (see FIG. 2) may be between about 1 micron and 10 microns, and, in a more specific embodiment, may be about 5 microns.

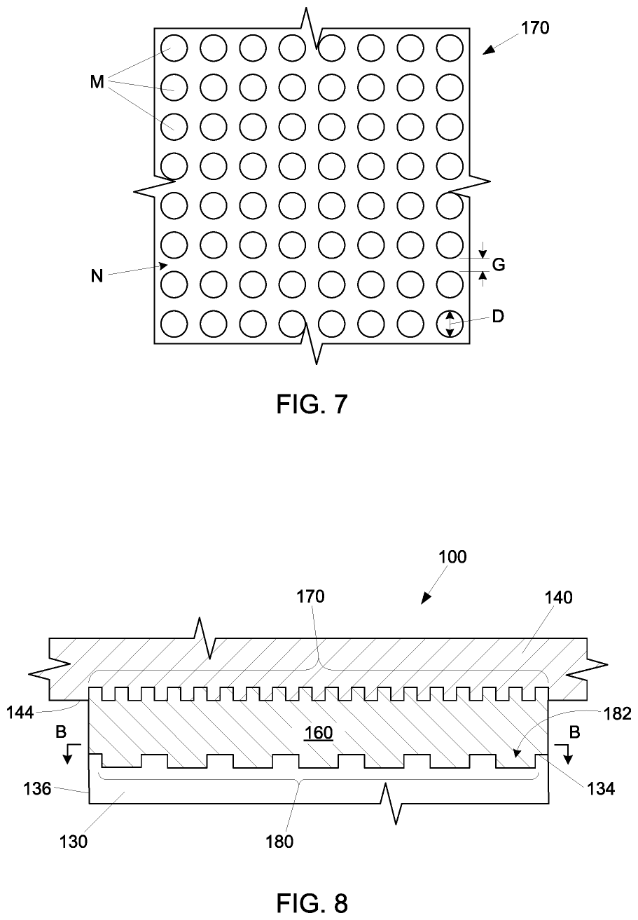

As shown in FIGS. 8-11, in addition to the surface area enhancement structure 170 of the heat dissipation device 140, a surface area enhancement structure 180 may be formed in or on the second surface 134 of the at least one integrated circuit device 130 to further assist in containing the thermal interface material 160. FIG. 8 illustrates at least one recess 182 extending into the at least one integrated circuit device 130 from the second surface 134 thereof. The at least one recess 182 may be formed by processes, including, but not limited to etching, laser ablating, ion bombardment, and the like. As shown in the FIGS. 9 and 10, the surface area enhancement structure 180 may be plurality of projections 186 extending from the second surface 134 of the integrated circuit device 130. In the embodiment shown in FIG. 9, the projections 186 may be formed by recessing the second surface 134 of the integrated circuit device 130 by processes, including but not limited to etching, laser ablating, ion bombardment, skiving, milling, and the like. In the embodiment shown in FIG. 10, the projections 186 may be formed after the formation of the heat dissipation device 140 by plating, build-up, lamination, and the like.

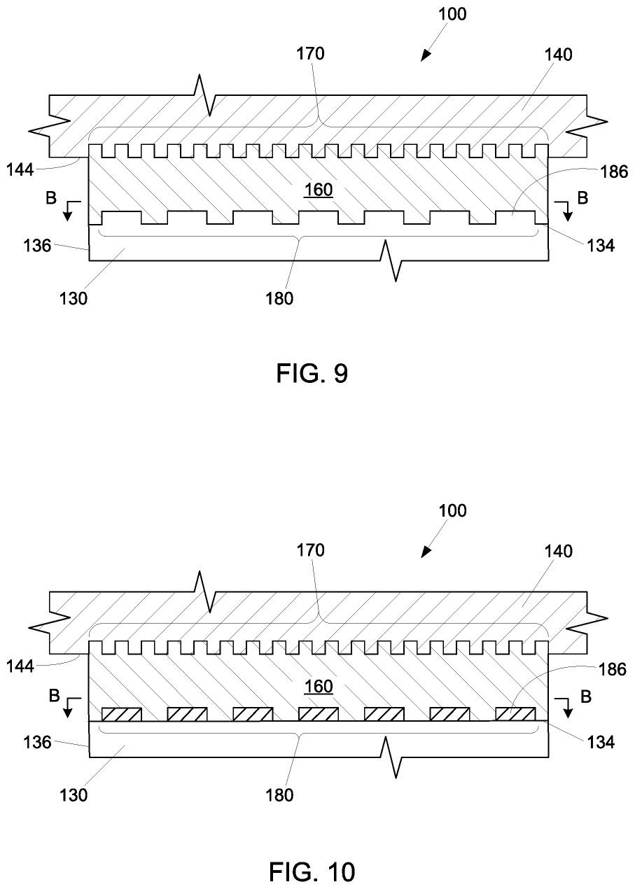

The recesses and projections, shown in FIGS. 8-10, may have any appropriate shape. For example, elements R may have a substantially square cross-section in FIG. 11 (plan view along line B-B without the thermal interface material 160 for clarity) and may be formed near or proximate the at least one side 136 of the integrated circuit device 130. Elements R may represent the plurality of individual recesses 182 with regard to the embodiment of FIG. 8, as discussed above, or elements R may represent the plurality of projections 186 with regard to the embodiments of FIGS. 9 and 10, as discussed above.

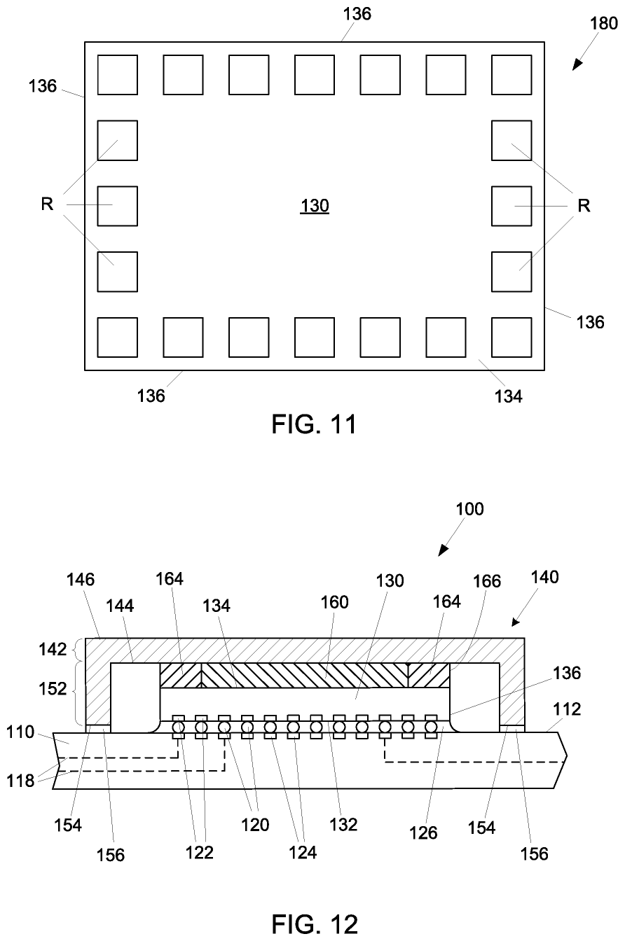

In one embodiment, as shown in FIG. 12, a sealant barrier 164 may be formed at the at least one side 136 of the integrated circuit device 130 as an additional defense to prevent the thermal interface material 160 from pumping/bleeding out from between the integrated circuit device 130 and the heat dissipation device 140. As shown in FIG. 12, the sealant barrier 164 may have at least one side 166 that is in substantially the same plane as the at least one side 136 of the at least one integrated circuit device 130.

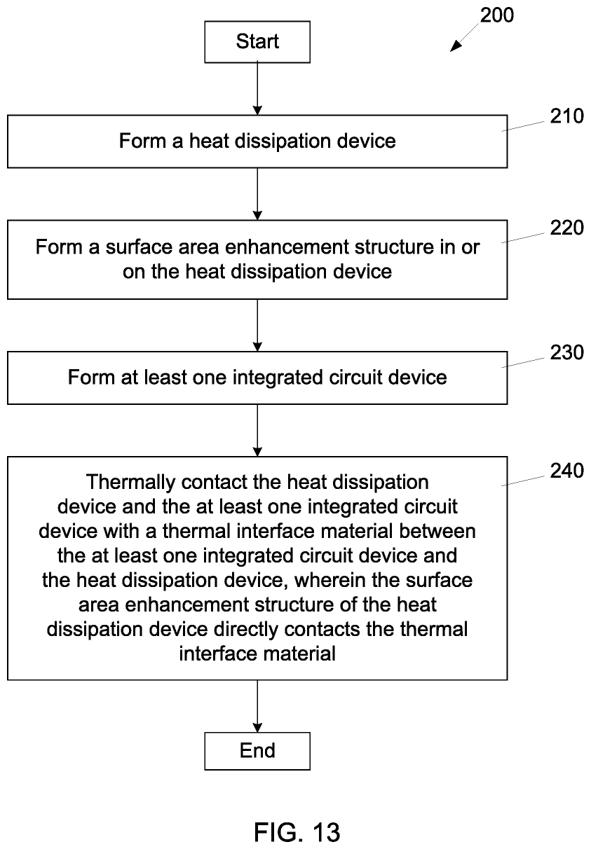

FIG. 13 is a flow chart of a process 200 of fabricating an integrated circuit assembly according to an embodiment of the present description. As set forth in block 210, a heat dissipation device may be formed. A surface area enhancement structure may be formed in or on the heat dissipation device, as set forth in block 220. As set forth in block 230, at least one integrated circuit device may be formed. The heat dissipation device and at least one integrated circuit device may be brought into thermal contact with a thermal interface material disposed between the heat dissipation device and the at least one integrated circuit device, wherein the surface area enhancement structure of the heat dissipation device directly contacts the thermal interface material, as set forth in block 240.

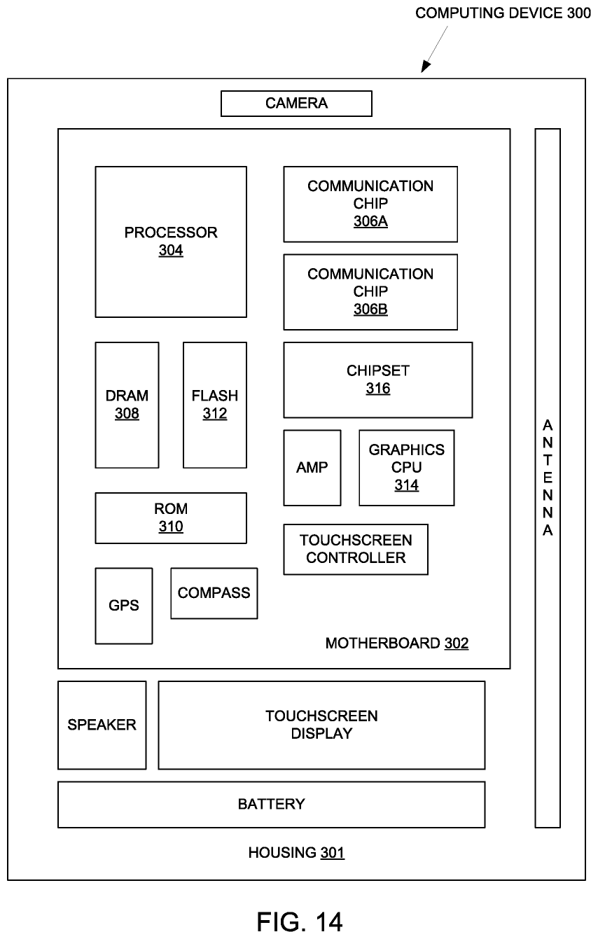

FIG. 14 illustrates an electronic or computing device 300 in accordance with one implementation of the present description. The computing device 300 may include a housing 301 having a board 302 disposed therein. The computing device 300 may include a number of integrated circuit components, including but not limited to a processor 304, at least one communication chip 306A, 306B, volatile memory 308 (e.g., DRAM), non-volatile memory 310 (e.g., ROM), flash memory 312, a graphics processor or CPU 314, a digital signal processor (not shown), a crypto processor (not shown), a chipset 316, an antenna, a display (touchscreen display), a touchscreen controller, a battery, an audio codec (not shown), a video codec (not shown), a power amplifier (AMP), a global positioning system (GPS) device, a compass, an accelerometer (not shown), a gyroscope (not shown), a speaker, a camera, and a mass storage device (not shown) (such as hard disk drive, compact disk (CD), digital versatile disk (DVD), and so forth). Any of the integrated circuit components may be physically and electrically coupled to the board 302. In some implementations, at least one of the integrated circuit components may be a part of the processor 304.

The communication chip enables wireless communications for the transfer of data to and from the computing device. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device may include a plurality of communication chips. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others.

The term “processor” may refer to any device or portion of a device that processes electronic data from registers and/or memory to transform that electronic data into other electronic data that may be stored in registers and/or memory.

At least one of the integrated circuit components may include at least one integrated circuit device, a heat dissipation device thermally contacting the at least one integrated circuit device, wherein the heat dissipation device includes a surface area enhancement structure, and a thermal interface material between the at least one integrated circuit device and the heat dissipation device, wherein the surface area enhancement structure of the heat dissipation device directly contacts the thermal interface material.

In various implementations, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device may be any other electronic device that processes data.

It is understood that the subject matter of the present description is not necessarily limited to specific applications illustrated in FIGS. 1-14. The subject matter may be applied to other integrated circuit devices and assembly applications, as well as any appropriate electronic application, as will be understood to those skilled in the art.

The follow examples pertain to further embodiments and specifics in the examples may be used anywhere in one or more embodiments, wherein Example 1 is a heat dissipation device, comprising a planar structure having a first surface, and a surface area enhancement structure projecting from or extending into the first surface of the planar structure.

In Example 2, the subject matter of Example 1 can optionally include the surface area enhancement structure of the heat dissipation device comprising at least one projection extending from the first surface of the planar structure of the heat dissipation device.

In Example 3, the subject matter of Example 1 can optionally include the surface area enhancement structure of the heat dissipation device comprising at least one recess extending into the first surface of the planar structure of the heat dissipation device.

In Example 4, the subject matter of any of Examples 1 to 3 can optionally include the at least one side structure extending from the first surface of the planar structure of the heat dissipation device.

In Example 5, an integrated circuit assembly may comprise at least one integrated circuit device; a heat dissipation device thermally contacting the at least one integrated circuit device, wherein the at least one heat dissipation device includes a surface area enhancement structure; and a thermal interface material between the at least one integrated circuit device and the heat dissipation device, wherein the surface area enhancement structure of the heat dissipation device directly contacts the thermal interface material.

In Example 6, the subject matter of Example 5 can optionally include the surface area enhancement structure of the heat dissipation device comprising at least one projection extending from the heat dissipation device.

In Example 7, the subject matter of Example 5 can optionally include the surface area enhancement structure of the heat dissipation device comprising at least one recess extending into the heat dissipation device.

In Example 8, the subject matter of any of Examples 5 to 7 can optionally include the at least one integrated circuit device including a surface area enhancement structure and wherein the surface area enhancement structure of the at least one integrated circuit device directly contacts the thermal interface material.

In Example 9, the subject matter of Example 8 can optionally include the surface area enhancement structure of the at least one integrated circuit device comprising at least one projection extending from the at least one integrated circuit device.

In Example 10, the subject matter of Example 8 can optionally include the surface area enhancement structure of the at least one integrated circuit device comprising at least one recess extending into the at least one integrated circuit device.

In Example 11, the subject matter of any of Examples 5 to 7 can optionally include a substrate, wherein the at least one integrated circuit device is electrically attached to the substrate.

In Example 12, the subject matter of Example 11 can optionally include the heat dissipation device being attached to the substrate.

In Example 13, the subject matter of any of Examples 5 to 7 can optionally include the thermal interface material being a two-phase metallic alloy.

In Example 14 is a method of fabrication an integrated circuit assembly may comprise forming a heat dissipation device, forming a surface area enhancement structure in or on the heat dissipation device, forming at least one integrated circuit device, and thermally contacting the heat dissipation device and the at least one integrated circuit device with a thermal interface material between the at least one integrated circuit device and the heat dissipation device, wherein the surface area enhancement structure of the heat dissipation device directly contacts the thermal interface material.

In Example 15, the subject matter of Example 14 can optionally include forming the surface area enhancement structure of the heat dissipation device comprising forming at least one projection extending from the heat dissipation device.

In Example 16, the subject matter of Example 14 can optionally include forming the surface area enhancement structure of the heat dissipation device comprising forming at least one recess extending into the heat dissipation device.

In Example 17, the subject matter of any of Examples 14 to 16 can optionally include forming a surface area enhancement structure on or in the at least one integrated circuit device and wherein the surface area enhancement structure of the at least one integrated circuit device directly contacts the thermal interface material.

In Example 18, the subject matter of Example 17 can optionally include forming the surface area enhancement structure of the at least one integrated circuit device comprising forming at least one projection extending from the at least one integrated circuit device.

In Example 19, the subject matter of Example 17 can optionally include forming the surface area enhancement structure of the at least one integrated circuit device comprising forming at least one recess extending into the at least one integrated circuit device.

In Example 20, the subject matter of any of Examples 14 to 16 can optionally include forming a substrate and electrically attaching the at least one integrated circuit device to the substrate.

In Example 21, the subject matter of Example 20 can optionally include attaching the heat dissipation device to the substrate.

In Example 22, the subject matter of any of Examples 5 to 7 can optionally include thermally contacting the heat dissipation device and the at least one integrated circuit device with a thermal interface material comprising thermally contacting the heat dissipation device and the at least one integrated circuit device with two-phase metallic alloy thermal interface material.

In Example 23, an electronic system may comprise a board and an integrated circuit package electrically attached to the board, wherein the integrated circuit package, comprises: at least one integrated circuit device; a heat dissipation device thermally contacting the at least one integrated circuit device, wherein the at least one heat dissipation device includes a surface area enhancement structure; and a thermal interface material between the at least one integrated circuit device and the heat dissipation device, wherein the surface area enhancement structure of the heat dissipation device directly contacts the thermal interface material.

In Example 24, the subject matter of Example 23 can optionally include the surface area enhancement structure of the heat dissipation device comprising at least one projection extending from the heat dissipation device.

In Example 25, the subject matter of Example 23 can optionally include the surface area enhancement structure of the heat dissipation device comprising at least one recess extending into the heat dissipation device.

In Example 26, the subject matter of any of Examples 23 to 25 can optionally include the at least one integrated circuit device including a surface area enhancement structure and wherein the surface area enhancement structure of the at least one integrated circuit device directly contacts the thermal interface material.

In Example 27, the subject matter of Example 26 can optionally include the surface area enhancement structure of the at least one integrated circuit device comprising at least one projection extending from the at least one integrated circuit device.

In Example 28, the subject matter of Example 26 can optionally include the surface area enhancement structure of the at least one integrated circuit device comprising at least one recess extending into the at least one integrated circuit device.

In Example 29, the subject matter of any of Examples 23 to 25 can optionally include a substrate, wherein the at least one integrated circuit device is electrically attached to the substrate.

In Example 30, the subject matter of Example 29 can optionally include the heat dissipation device being attached to the substrate.

In Example 31, the subject matter of any of Examples 23 to 25 can optionally include the thermal interface material being a two-phase metallic alloy.

Having thus described in detail embodiments of the present invention, it is understood that the invention defined by the appended claims is not to be limited by particular details set forth in the above description, as many apparent variations thereof are possible without departing from the spirit or scope thereof

What is claimed is:

1. An integrated circuit assembly, comprising:
at least one integrated circuit device;
a heat dissipation device thermally contacting the at least one integrated circuit device, wherein the heat dissipation device includes a surface area enhancement structure; and
a thermal interface material between the at least one integrated circuit device and the heat dissipation device, wherein the surface area enhancement structure of the heat dissipation device directly contacts the thermal interface material.

2. The integrated circuit assembly of claim 1, wherein the surface area enhancement structure of the heat dissipation device comprises at least one projection extending from the heat dissipation device.

3. The integrated circuit assembly of claim 1, wherein the surface area enhancement structure of the heat dissipation device comprises at least one recess extending into the heat dissipation device.

4. The integrated circuit assembly of claim 1, wherein the at least one integrated circuit device includes a surface area enhancement structure and wherein the surface area enhancement structure of the at least one integrated circuit device directly contacts the thermal interface material.

5. The integrated circuit assembly of claim 4, wherein the surface area enhancement structure of the at least one integrated circuit device comprises at least one projection extending from the at least one integrated circuit device.

6. The integrated circuit assembly of claim 4, wherein the surface area enhancement structure of the at least one integrated circuit device comprises at least one recess extending into the at least one integrated circuit device.

7. The integrated circuit assembly of claim 1, further comprising a substrate, wherein the at least one integrated circuit device is electrically attached to the substrate.

8. The integrated circuit assembly of claim 7, wherein the heat dissipation device is attached to the substrate.

9. The integrated circuit assembly of claim 1, wherein the thermal interface material comprises a two-phase metallic alloy.

10. A method of fabricating an integrated circuit assembly, comprising:
forming a heat dissipation device;
forming a surface area enhancement structure in or on the heat dissipation device;
forming at least one integrated circuit device; and
thermally contacting the heat dissipation device and the at least one integrated circuit device with a thermal interface material between the at least one integrated circuit device and the heat dissipation device, wherein the surface area enhancement structure directly contacts the thermal interface material.

11. The method of claim 10, wherein forming the surface area enhancement structure of the heat dissipation device comprises forming at least one projection extending from the heat dissipation device.

12. The method of claim 10, wherein forming the surface area enhancement structure of the heat dissipation device comprises forming at least one recess extending into the heat dissipation device.

13. The method of claim 10, further comprises forming a surface area enhancement structure on or in the at least one integrated circuit device and wherein the surface area enhancement structure of the at least one integrated circuit device directly contacts the thermal interface material.

14. The method of claim 13, wherein forming the surface area enhancement structure of the at least one integrated circuit device comprises forming at least one projection extending from the at least one integrated circuit device.

15. The method of claim 13, wherein forming the surface area enhancement structure of the at least one integrated circuit device comprises forming at least one recess extending into the at least one integrated circuit device.

16. The method of claim 10, further comprising forming a substrate and electrically attaching the at least one integrated circuit device to the substrate.

17. The method of claim 16, further comprising attaching the heat dissipation device to the substrate.

18. The method of claim 10, wherein thermally contacting the heat dissipation device and the at least one integrated circuit device with a thermal interface material comprises thermally contacting the heat dissipation device and the at least one integrated circuit device with two-phase metallic alloy thermal interface material.

19. An electronic system, comprising:
a board; and
an integrated circuit package electrically attached to the board, wherein the integrated circuit package comprises:
at least one integrated circuit device;
a heat dissipation device thermally contacting the at least one integrated circuit device, wherein the heat dissipation device includes a surface area enhancement structure; and
a thermal interface material between the at least one integrated circuit device and the heat dissipation device, wherein the surface area enhancement structure of the heat dissipation device directly contacts the thermal interface material.

20. The electronic system of claim 19, wherein the surface area enhancement structure of the heat dissipation device comprises at least one projection extending from the heat dissipation device.

21. The electronic system of claim 19, wherein the surface area enhancement structure of the heat dissipation device comprises at least one recess extending into the heat dissipation device.

22. The electronic system of claim 19, wherein the at least one integrated circuit device includes a surface area enhancement structure and wherein the surface area enhancement structure of the at least one integrated circuit device directly contacts the thermal interface material.

23. The electronic system of claim 22, wherein the surface area enhancement structure of the at least one integrated circuit device comprises at least one projection extending from the at least one integrated circuit device.

24. The electronic system of claim 22, wherein the surface area enhancement structure of the at least one integrated circuit device comprises at least one recess extending into the at least one integrated circuit device.

25. The electronic system of claim 19, wherein the thermal interface material comprises a two-phase metallic alloy.
